(19) United States
(12) Patent Application Publication
(10) Pub. No.: US 2026/0157130 A1
(43) Pub. Date: Jun. 4, 2026

(54) MICROELECTRONIC DEVICE PACKAGE WITH BACKSIDE CAVITY IN SEMICONDUCTOR DIES AND METHODS

(71) Applicant: Texas Instruments Incorporated, Dallas, TX (US)

(72) Inventors: You Chye How, Melaka (MY); Huay Yan Tay, Bukit Baru (MY); Wei Li Julien Mok, Melaka (MY)

(21) Appl. No.: 18/964,429

(22) Filed: Nov. 30, 2024

(51) Int. Cl. H01L 23/00; H01L 21/3065; H01L 21/78; H01L 23/495

(52) U.S. Cl. CPC H10P 50/244; H10P 54/00; H10W 70/417; H10W 72/0198; H10W 72/073; H10W 72/342; H10W 72/354; H10W 72/884; H10W 90/736; H10W 90/756

(57) ABSTRACT

A described example apparatus includes: at least one semiconductor die mounted on a die pad of a package substrate, the at least one semiconductor die having a cavity extending into a backside surface and having edges on the backside surface around the cavity; die attach material adhering the at least one semiconductor die to the die pad, the die attach material positioned within the cavity, the edges around the cavity contacting a device side surface of the die pad directly; electrical connections between bond pads on the device side surface of the at least one semiconductor die and leads of the package substrate; and mold compound covering the semiconductor die, the electrical connections, and a portion of the package substrate, while the board side surface of the terminals is exposed from the mold compound, the mold compound forming the body of a microelectronic device package.

### TECHNICAL FIELD

This disclosure relates generally to microelectronic device packages, and more particularly to a method for fabrication of a microelectronic device package incorporating semiconductor dies mounted with die attach materials.

### BACKGROUND

Semiconductor dies are produced for use in electronic circuits using semiconductor wafer manufacturing facilities (sometimes referred to as “wafer fabs”) to form semiconductor dies on a device side surface of a semiconductor wafer. Example semiconductor wafer materials include silicon, germanium, gallium arsenide, gallium nitride, sapphire, silicon carbide and indium phosphide, with silicon being the most used semiconductor wafer material. Example wafer fabrication processes for making semiconductor dies include ion implantation, thermal anneals, thermal oxidation, chemical vapor deposition, dielectric deposition, conductor deposition, sputtering, damascene deposition, chemical mechanical polishing, and passivation layer deposition.

Once the semiconductor dies are complete, the individual devices are removed from the semiconductor wafer by a process referred to as “singulation.” After the semiconductor wafer is diced into individual semiconductor dies, the individual semiconductor dies can be mounted to a package substrate and a microelectronic device package is formed. In an example process, the individual semiconductor dies are mounted to a die pad, with bond pads on the semiconductor dies facing away from the die pad. A die attach film or die attach epoxy can be used to attach the semiconductor die to the die pad. Electrical connections can be formed between the semiconductor die and leads of the package substrate, for example wire bonds can be formed to couple bond pads on the semiconductor die to the leads of the package substrate. In some microelectronic device packages, a die pad is used as a ground. When wire bond connections are made to the bond pads of the semiconductor dies, some connections are “downbond” connections to the die pad. The need for these connections creates a “keep out zone” for the die pad, a space where wire bonds will be made on the die pad, and it is critical for the wire bonding process to be reliable that other materials are not present in the “keep out zone” of “KOZ”. The semiconductor dies can be attached to the die pad using die attach material. A cost-effective approach is to deposit die attach epoxy as a liquid and mount the dies using the die attach epoxy, which is then cured. The die attach epoxy extends beyond the edges of the rectangular semiconductor dies. However, issues occur when die attach epoxy spreads into the keep out zone on the die pad, by a phenomenon called “epoxy bleed out.” The wire bonds need to be formed away from the die attach epoxy. As the size of increasingly integrated semiconductor dies increases, the area of the semiconductor dies also increases. If a large space is outside the die area is needed to prevent die attach epoxy from bleeding into the keep out zone for these larger semiconductor dies, the die pad area is necessarily increased, and the overall package size is also increased-which is in conflict with an increasing desire for smaller device packages. In addition, some microelectronic device packages mount multiple semiconductor dies, and increased area needed for preventing die attach epoxy interfering with wire bonds increases the die pad area for these packages even further. In addition, the number of different die pad sizes needed for the various packages results in a large inventory of different package substrates needed for different semiconductor dies, increasing costs.

After the electrical connections are formed, a package body can be formed using a mold compound. For example, a transfer molding process can be used to cover the semiconductor die, the electrical connections, and portions of the package substrate with the mold compound, while portions of leads are left exposed from the mold compound to form terminals for the microelectronic device package.

Improvements are needed for producing reliable and robust microelectronic device packages where semiconductor dies area attached to a package substrate with die attach epoxy, without the need to increase area of the die pads to avoid epoxy bleed out defects, and at reasonable cost.

### SUMMARY

In a described example arrangement, an apparatus includes: at least one semiconductor die mounted on a die pad of a package substrate, the at least one semiconductor die having a device side surface and an opposite backside surface, the at least one semiconductor die having a cavity extending into the backside surface and having edges on the backside surface around the cavity; die attach material adhering the at least one semiconductor die to the die pad, the die attach material positioned within the cavity extending into the backside surface, the edges around the cavity contacting a device side surface of the die pad directly; electrical connections between bond pads on the device side surface of the at least one semiconductor die and leads formed in the device side layer of the package substrate, the leads having portions forming terminals and having a board side surface; and mold compound covering the semiconductor die, the electrical connections, and a portion of the package substrate, while the board side surface of the terminals is exposed from the mold compound, the mold compound forming the body of a microelectronic device package for the at least one semiconductor die.

In a described example method arrangement, the method includes: forming semiconductor dies on a device side surface of a semiconductor substrate, the semiconductor substrate having a backside surface opposite the device side surface; forming cavities extending into the backside surface of the semiconductor substrate, the cavities extending into a backside surface of the semiconductor dies and being surrounded by edges of the backside surface of the semiconductor dies; separating the semiconductor dies one from another by dicing the semiconductor substrate into individual semiconductor dies; dispensing die attach epoxy onto die pads of unit leadframes on a leadframe array, the unit leadframes having leads spaced from the die pads arranged for electrical connections; positioning the semiconductor dies over the die pads of the unit leadframes; mounting the semiconductor dies onto the die pads using the die attach epoxy, the die attach epoxy being positioned within the cavities extending into the backside surface of the semiconductor dies, wherein the edges of the backside surface are in contact with a device side surface of the die pads; forming electrical connections between bond pads on the semiconductor dies and leads of the leadframes; covering the semiconductor dies, the electrical connections, and portions of the unit leadframes with mold compound, the mold compound forming bodies for microelectronic device packages, and portions of the leads exposed from the mold compound to form terminals for the microelectronic device packages; and separating the unit leadframes one from another and from the leadframe array to form individual microelectronic device packages.

In another example method, the method includes: forming semiconductor dies on a device side surface of a semiconductor substrate, the semiconductor substrate having a backside surface opposite the device side surface; forming cavities extending into the backside surface of the semiconductor substrate, the cavities extending into a backside surface of the semiconductor dies and being surrounded by edges of the backside surface of the semiconductor dies; dispensing die attach epoxy into the cavities on the backside surface of the semiconductor substrate, the die attach epoxy contained within the cavities, the edges of the backside surface of the semiconductor dies being free from the die attach epoxy; separating the semiconductor dies one from another by dicing the semiconductor substrate into individual semiconductor dies; positioning the semiconductor dies over die pads of unit leadframes of a leadframe array, the unit leadframe having leads spaced from the die pads and arranged for electrical connections; using the die attach epoxy in the cavities extending into the backside surface of the semiconductor dies, mounting the semiconductor dies to the die pads, wherein the edges of the backside surface are in contact with a device side surface of the die pads; forming electrical connections between bond pads on the semiconductor dies and leads of the unit leadframes; covering the semiconductor dies, the electrical connections, and portions of the unit leadframes with mold compound, the mold compound forming bodies for microelectronic device packages, and portions of the leads of the unit leadframes exposed from the mold compound to form terminals for the microelectronic device packages; and separating the unit leadframes one from another and from the leadframe array to form individual microelectronic device packages.

### BRIEF DESCRIPTION OF THE DRAWINGS

FIG. 1A- B illustrate, in projection views, a semiconductor wafer and an individual semiconductor die, respectively.

FIGS. 2A-2B illustrate, in a projection view from a top side, and a cross-sectional view, respectively, an example arrangement for a microelectronic device package.

FIGS. 3A-3G illustrate, in a series of cross-sectional views, selected steps for forming an arrangement.

FIGS. 4A-4E illustrate, in another series of cross-sectional views, selected steps for forming a microelectronic device package in another arrangement.

FIGS. 5A-5D illustrate, in additional cross-sectional views, selected steps for forming additional alternative arrangements.

FIG. 6A-6E illustrate, in plan views, additional details of an arrangement.

FIGS. 7A-7D illustrate in plan views and corresponding cross-sectional views, alternative arrangements.

FIG. 8 illustrates in a flow diagram selected steps of a method for forming an arrangement.

FIG. 9 illustrates in a further flow diagram, selected steps of a method for forming an alternative arrangement.

### DETAILED DESCRIPTION

Corresponding numerals and symbols in the different figures generally refer to corresponding parts, unless otherwise indicated. The figures are not necessarily drawn to scale.

The term “scribe lane” is used herein. A scribe lane is a portion of semiconductor wafer between semiconductor dies. Sometimes in related literature the term “scribe street” is used. Once processing is finished and the semiconductor devices are complete, the semiconductor devices are separated into individual semiconductor dies by severing the semiconductor wafer along the scribe lanes. The separated dies can then be removed and managed individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “package substrate” is used herein. A package substrate is a substrate that includes conductive leads arranged to be coupled to a semiconductor die in a semiconductor device package, and to support the semiconductor die. Examples of package substrates useful with the arrangements include leadframes, pre-molded leadframes (“PMLF”), molded interconnect substrates (“MIS”), partially etched or half-etched leadframes, and multilayer substrates including additive build-up substrates such as substrates formed with Ajinomoto Build-Up Film (“ABF”) that is commercially available from the Ajinomoto Co. Inc., in Tokyo Japan, and other laminated substrates. In an example useful with the arrangments, a package substrate is provided with a strip of device units, each device unit is arranged to provide leads and support for a semiconductor die to be packaged as a semiconductor device package. Note that while a device unit can be a portion of a leadframe, the “frame” portion of a leadframe is removed during packaging to free the individual leads from one another, so to avoid any misinterpretation or confusion, the term “device unit” is used herein for a single unit of a package substrate strip, the device unit includes leads and supports the semiconductor die during packaging and in the semiconductor device package. The package substrate strip can be a leadframe strip with unit leadframes, but can also be a molded interconnect substrate strip, a routable leadframe strip, or other substrate strip used for packaging semiconductor devices.

The term “microelectronic device package” is used herein. A microelectronic device package is a package that provides protection for one or more devices, the devices can include a semiconductor die, several semiconductor dies, or passive components such as diodes, capacitors, resistors, inductors, transformers, coils, and sensors. The semiconductor dies can be mounted to the package substrate and can be mounted spaced from one another or can be stacked vertically. In some examples passive components can be integrated within a semiconductor die or can be in a discrete package mounted with the semiconductor die, to form a package-in-package device. Semiconductor device packages containing a single semiconductor die are also microelectronic device packages. In an example arrangement, a quad flat no-lead (QFN) package is described. QFN packages are increasingly used for microelectronic device packages. QFN packages have terminals exposed from the mold compound that forms the protective body of the package on a board side surface for mounting to a system board or module, a quad flat no-lead package has terminals on four sides. The terminals are approximately coextensive with the sides of the package body, and so the board area needed to mount a QFN package is reduced (when compared to “leaded” microelectronic device packages where terminals extend away from the package body.) Other package types can be used with the arrangements, for example dual in-line (“DIP”) packages have leads that extend from two sides, while quad plastic packages can have leads that extend from four sides, while other no-lead packages can have terminals exposed for mounting on the board side surface of only two sides of the package, for example.

The term “saw street” is used herein. Saw streets are areas between the semiconductor device packages on a package substrate that provide areas for sawing between the semiconductor device packages.

Elements are described herein as “coupled.” As used herein, the term “coupled” includes elements that are directly connected, and elements that are electrically connected even with intervening elements or wires are also coupled.

The term “semiconductor die” is used herein. A semiconductor die can be a discrete semiconductor device such as a bipolar transistor, a few discrete devices such as a pair of power field effect transistor (FET) switches fabricated together on a single semiconductor die, or an integrated circuit with multiple semiconductor devices in a circuit such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory semiconductor device. The semiconductor die can be a passive device such as a sensor, example sensors include photocells, transducers, and charge coupled devices (CCDs), or can be a micromechanical device, such as a digital micromirror device (DMD) or a microelectromechanical system (MEMS) device.

The term “downbond” is used herein. In a wire bonded package, a “downbond” is a bond wire connection between a bond pad on the device side surface of a semiconductor die and a die pad, which is formed instead of making an electrical connection to a package lead. In example arrangements, downbond connections are made between a semiconductor die and a die pad, or between a semiconductor die and a power rail in a package substrate. In contrast to prior approaches, in one advantage accrued by use of the arrangements, die attach epoxy will not be present in wire bonding areas on die pads, or bleed into areas where downbond connections are to be formed. The advantages of the arrangements include improving downbond reliability in wire bonded microelectronic device packages.

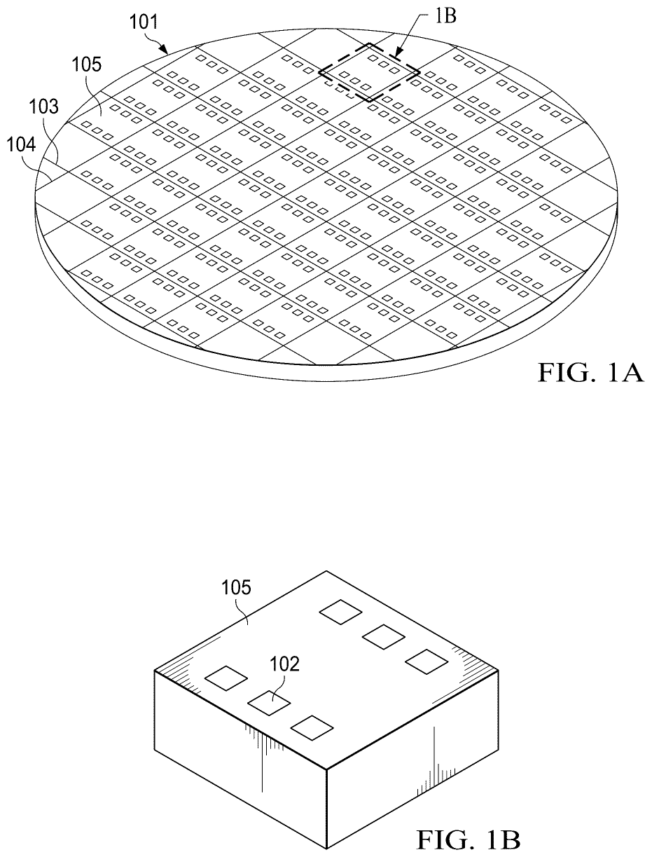

In FIG. 1A, semiconductor substrate, which is a semiconductor wafer 101, is shown with an array of semiconductor dies 105 arranged in rows and columns. The semiconductor dies 105 can be formed using manufacturing processes in a semiconductor manufacturing facility (sometimes referred to as a “wafer fab”), the processes can include ion implantation for carrier doping of semiconductor substrates, anneals, oxidation, dielectric and conductor deposition, photolithography, pattern, etch, chemical mechanical polishing (CMP), electroplating, via formation and other processes used when making semiconductor devices. Devices (not shown for clarity) are formed on a device side surface of the semiconductor dies 105 during the manufacturing processes. Scribe lanes 103 and 104, which are perpendicular to one another, and which run in parallel groups across the semiconductor substrate, wafer 101, separate the rows and columns of the completed semiconductor dies 105, and the scribe lanes 103, 104 provide areas for dicing the wafer to separate the semiconductor dies 105 from one another.

FIG. 1B illustrates in a projection view a single semiconductor die 105 from the semiconductor wafer 101 in FIG. 1A, with bond pads 102 on a device side surface, bond pads 102 are conductive pads that are electrically coupled to the devices (the devices are not shown for simplicity of illustration) formed in the semiconductor die 105. The semiconductor dies 105 can be separated from semiconductor wafer 101 by wafer dicing and are said to be “singulated” from one another, using the scribe lanes 103, 104 (see FIG. 1A).

Dicing processes can be used to singulate the dies 105 from the semiconductor wafer 101. Mechanical saw dicing can be used. Plasma dicing can also be used. The minimum width of the scribe lanes needed for plasma dicing is substantially less than the minimum scribe lane widths required for either laser dicing or mechanical saw dicing, increasing the number of semiconductors dies that can be formed on a single semiconductor wafer, and increasing yields, which can lower unit costs. However, other types of wafer dicing can be used with the arrangements, including laser dicing. The sides of semiconductor dies 105 can have varied appearance depending on the type of dicing used. When plasma dicing is used, the sides of the material etched during the plasma dicing can have a “scalloped” appearance due to the repetitive process used, as is further described below. Laser dicing can create stress lines or fractures that will appear on the sides of the diced semiconductor dies. Mechanical dicing using a rotating saw blade can leave abraded features or saw blade marks along the sides of the semiconductor dies after dicing.

The semiconductor die 105 of FIG. 1B is shown with bond pads 102 ready for wire bonding. The bond pads 102 are prepared to be electrically connected to conductive leads of a package substrate by forming wire bonds. Wire bonds can be formed using bond wires that bond to and couple the bond pads 102 to conductive portions of leads of the package substrate, such as a leadframe.

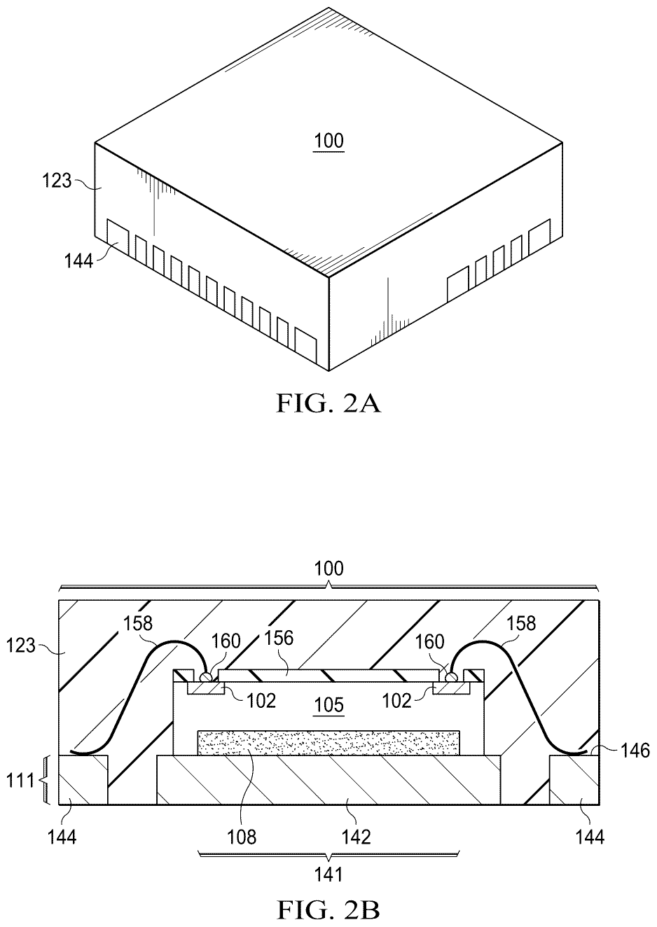

FIG. 2A illustrates, in a projection view, a microelectronic device package of an example arrangement. FIG. 2B illustrates, in a cross-sectional view, the microelectronic device package of FIG. 2A.

In FIG. 2A, microelectronic device package 100 is shown in a projection view from a top side surface. Microelectronic device package 100 is a QFN type package. Mold compound 123 forms a package body that covers and protects at least one semiconductor die (not visible in FIG. 2A, but see semiconductor die 105 in FIG. 2B) and the electrical connections made from the semiconductor die to leads of the package subtrate. In the illustrated example, leads of a package substrate are partially covered by mold compound 123, with exposed surfaces of the leads forming terminals 144. The terminals 144 have exposed surfaces on at least a board side surface of the microelectronic device package 100. The terminals 144 can be used to mount the device to a board or module using surface mount technology (“SMT”), which uses solder to form physical connections and electrical connections between the microelectronic device package terminals 144 and conductive lands on a board or module.

FIG. 2B illustrates the microelectronic device package 100 of FIG. 2A in a cross-sectional view. In FIG. 2B, at least one semiconductor die 105 is shown mounted to a package substrate 111, which in this example arrangement is a conductive leadframe. In addition to the example arrangement with a single semiconductor die as is shown in FIG. 2B, in alternative arrangements additional passive components or additional semiconductor dies can be mounted in microelectronic device package 100.

The semiconductor die 105 is shown attached to a die pad 142 of package substrate 111 by a die attach material 108. In the arrangements, the die attach material 108 can be an epoxy that is placed in a cavity 141 that extends into a backside surface of the semiconductor die 105. The die attach material 108 is in contact with the interior of the cavity 141 and a device side surface of the die pad 142. Cavity 141 has sides extending from the backside surface into the semiconductor die and has an internal bottom surface. The die attach epoxy 108 is contained by the sides of the cavity 141 in the semiconductor die 105, so that during die mounting processes to mount the semiconductor die 105 to the die pad 142 of the package substrate 111, the die attach epoxy 108 does not bleed out onto the die pad 142 outside of the area of the semiconductor die 105. In one approach for forming arrangements, individual semiconductor dies 105 with cavity 141 are mounted to a die pad 142 using die attach epoxy that is previously deposited on the die pad 142, the cavity 141 containing the die attach epoxy 108 during mounting. The die attach epoxy 108 has a backside surface that is coplanar with the edges of the device side surface of the semiconductor die 105 surrounding the cavity 141. In another approach, arrangements are formed in a wafer scale process where cavities on the backsides of semiconductor dies on a semiconductor wafer are filled with a B-stage die attach epoxy at the wafer level of processing, and the semiconductor dies are subsequently singulated from the semiconductor wafer, each semiconductor die including the die attach epoxy in a backside cavity, the B-stage die attach epoxy is then used to mount the semiconductor dies to the die pads of the package substrates.

Returning to FIG. 2B, electrical connections, in this example wire bonds 158, are shown attached to bond pads 102 by ball bonds 160. In an alternative arrangement ribbon bonds can be used to form the electrical connections. A protective dielectric layer such as a polyimide (PI) 156 covers the device side surface of the semiconductor die 105, while the bond pads 102 are exposed from the PI layer 156. The wire bonds 158 extend to and electrically connect to the device side surface 146 of terminals 144. The mold compound 123 covers the electrical connections 158, with the terminals 144 having at least a board side surface exposed from the mold compound 123.

Use of the arrangements retains the die attach epoxy 108 within the area of the semiconductor die 105. This advantageously allows different semiconductor dies to be mounted using a same package substrate or using a common leadframe design for various microelectronic device packages, which can reduce the number of leadframe designs needed to support a packaging of a variety of semiconductor dies. In an advantage provided by use of the arrangements, package substrate designs can be reused for various semiconductor die sizes. Reuse of package substrate designs for different semiconductor dies can reduce the need to manufacture, test and store many different package substrates, instead various semiconductor dies can be mounted on the same leadframe design, reducing costs.

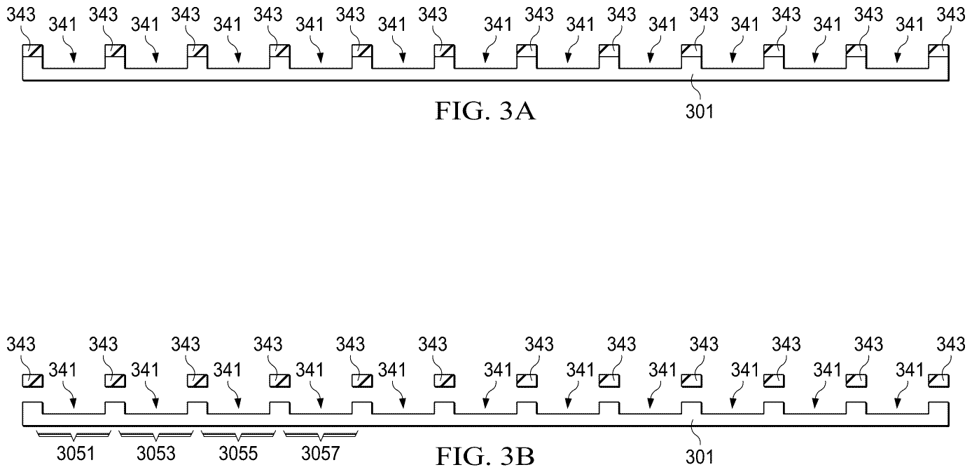

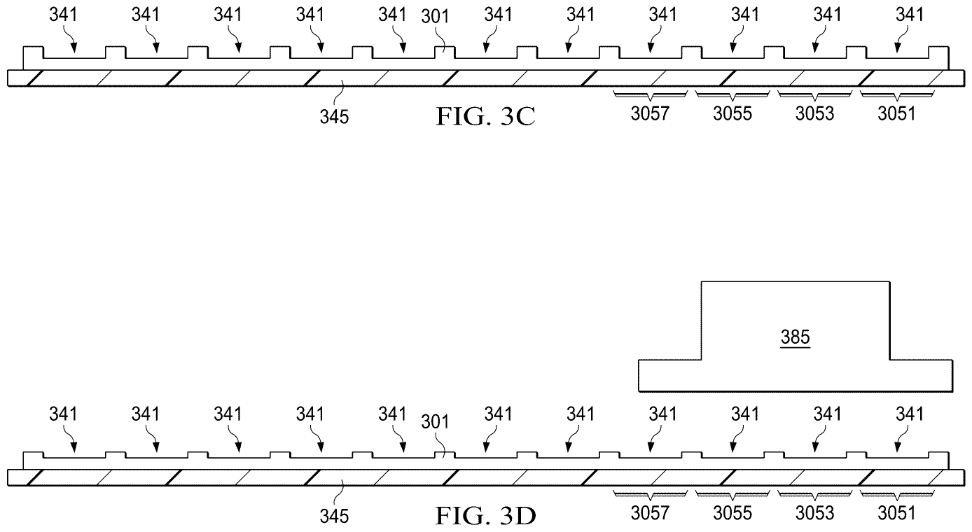

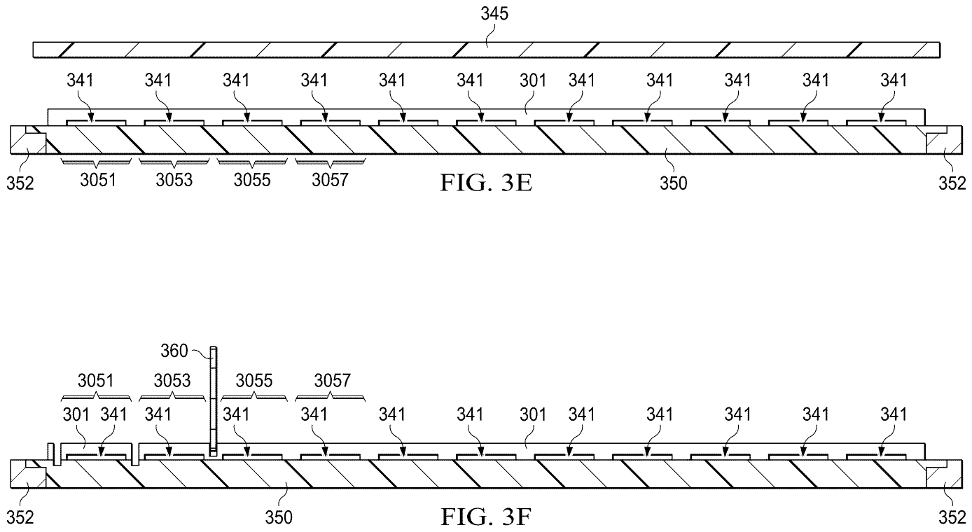

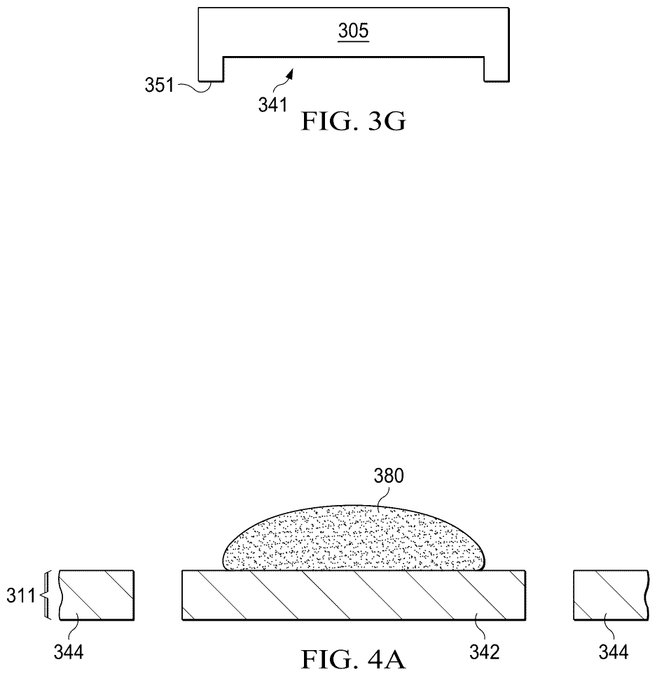

FIGS. 3A-3G illustrate, in a series of cross-sectional views, selected steps that can be used in forming an example arrangement. At FIG. 3A, a semiconductor wafer 301 is shown in a backside etch process. In an example etch process useful with the arrangements, the semiconductor wafer 301 is first processed to form devices (not shown for simplicity of illustration) on a device side surface in front-end processes in a wafer manufacturing facility. In FIG. 3A, the semiconductor wafer 301 is shown in a backside plasma etch process. The semiconductor wafer 301 has a photoresist layer 343 applied to the backside surface. In one example process useful with the arrangements, the photoresist 343 can be a dry film layer. Photoresist 343 has been patterned to define exposed areas corresponding to cavities 341 that are shown extending into the backside surface for each of many semiconductor dies formed on the semiconductor wafer 301. In an example semiconductor plasma etch process useful with the arrangements, a Bosch plasma etch process can be used. Because a plasma etch process tends to be anisotropic, the Bosch process was developed to enable forming etched openings with more or less vertical sides. In the Bosch process, the gasses used in a plasma chamber are varied to alternatively deposit protective material and to plasma etch, so that as an etched opening deepens into the semiconductor wafer in repeated etch cycles, the sidewalls are protected by depositing material between the etch cycles to maintain the vertical shape. In a repetitive process, the opening is deepened with the sides of the etched cavities remaining more or less vertical (when compared to the backside surface, which is shown in the figures in a horizontal orientation). The sides of the cavities 341 formed in the Bosch process can have scalloped shaped sidewalls (not visible in the illustrations), due to the repeated cycles deposit of protective material and etch of the wafer.

FIG. 3B illustrates a photoresist removal step applied to the elements of FIG. 3A. After the plasma etch is completed, a photoresist removal process, such as a dry film photoresist peel step, can be used to remove the photoresist 343 from the wafer. Alternative photoresist removal processes that can be used include plasma ashing to remove the photoresist 343. The plasma etch processes of FIGS. 3A-3B results in cavities 341 formed in the backside of semiconductor dies 3051, 3053, 3055, etc. formed in semiconductor wafer 301. A semiconductor wafer 301 can have tens, hundreds or even thousands of semiconductor dies arranged in rows and columns, (see for example FIG. 1A, and semiconductor dies 105 arranged on semiconductor wafer 101.) In the arrangements, a cavity such as one of cavities 341 is formed on a backside surface of each of the semiconductor dies 3051, 3053, etc.

FIG. 3C illustrates, in another cross-sectional view, the elements of FIG. 3B after an additional process step. In FIG. 3C, the semiconductor wafer 301 has a front side surface mounted to a backside grinding tape 345, which supports and stabilizes the semiconductor wafer 301 while exposing the backside surface for further processing. Cavities 341 are shown on the backside surface.

FIG. 3D illustrates, in a further cross-sectional view, an additional processing step. A backgrinding process is used to thin the semiconductor wafer 301 by removing a portion of the semiconductor wafer 301 by grinding from the backside. In an example process that can be used in forming an arrangement, a mechanical grinding tool 385 can be used to remove semiconductor material. The cavities 341 then become shallower as the backside of the semiconductor wafer 301 is processed. By controlling the amount of wafer thinning used, the depth of the cavities 341 can be further controlled.

FIG. 3E illustrates, in a further cross-sectional view, the elements of FIG. 3D after the backside side of the semiconductor wafer 301 is mounted to a dicing tape 350. The dicing tape 350 can be provided in a frame or mount 352 that supports the dicing tape 350. The backgrinding tape 345 is shown being removed from the device side of the semiconductor wafer 301.

FIG. 3F illustrates, in a further cross-sectional view, the elements of FIG. 3E during a wafer dicing operation. A mechanical sawblade 360 is shown cutting through the semiconductor wafer 301 between semiconductor dies such as 3051 that are formed in rows and columns on the semiconductor wafer 301. The semiconductor dies such as semiconductor die 3051 have cavities 341 extending into the backside. The dicing tape 350 supports and secures the semiconductor dies such as semiconductor die 3051 during and after the sawblade 360 traverses the saw streets in the semiconductor wafer 301. A frame 352 can support the dicing tape 350. Alternative methods for wafer dicing can be used with the arrangements, such as plasma dicing, or laser dicing. The sides of the semiconductor dies 3051, 3053 etc. will have a different surface finish depending on the type of dicing used to singulate the devices. Rotating mechanical saw blades can leave abrasion marks on the sides, while a plasma dicing tool can leave scalloped sides as described above.

FIG. 3G illustrates a single semiconductor die 305 taken from the semiconductor wafer 301 after the singulation process shown in FIG. 3F. The semiconductor die 305 has a cavity 341 extending into the backside surface. The cavity 341 has sidewalls on four sides so that when the semiconductor die 305 is subsequently mounted to a package substrate using die attach material, the die attach material can be contained within the cavity 341, the use of the arrangements therefore preventing the epoxy bleed out problems that can occur when using prior die mount approaches. The semiconductor die 305 has edges 351 on the backside surface that surround the cavity 341.

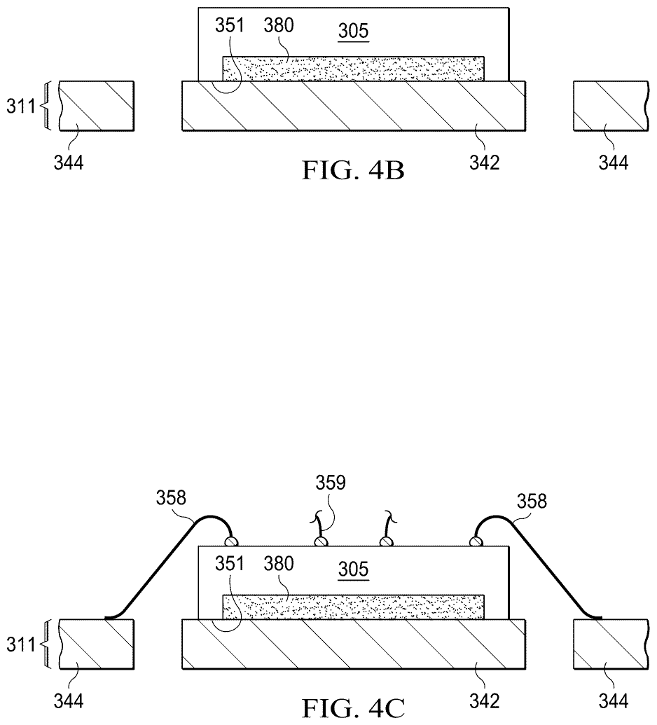

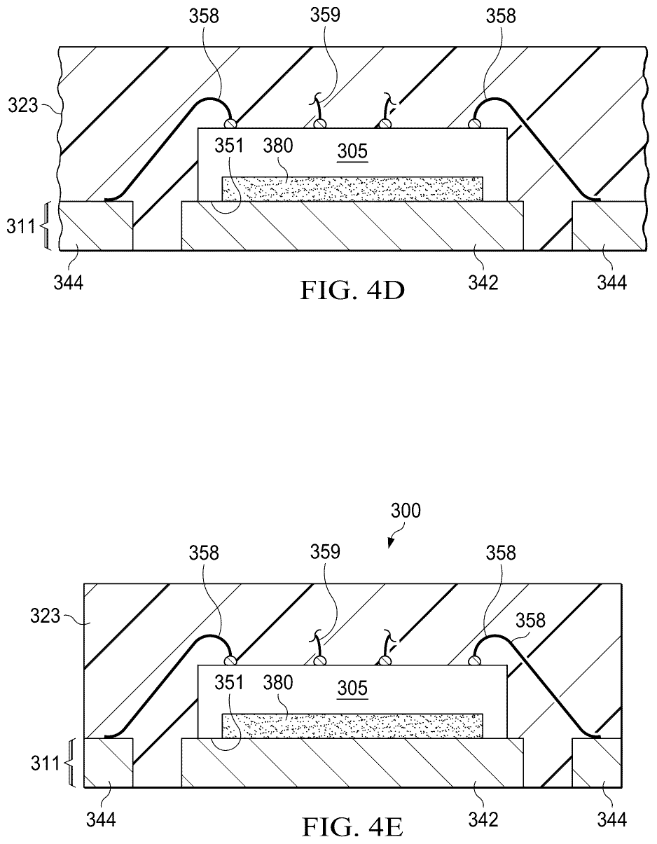

FIGS. 4A-4F illustrate, in another series of cross-sectional views, steps that can be used to form a microelectronic device package using a semiconductor die of the arrangements.

In FIG. 4A, a cross-sectional view illustrates a unit portion of package substrate 311. In this illustrated example a conductive leadframe is used for package substrate 311, with a die pad 342 and having leads 344 spaced from the die pad 342. Die attach epoxy 380 is shown deposited on a device side surface of die pad 342. The die attach epoxy 380 can be deposited, in one approach that can be used with the arrangements, using a needle dispenser. Drop-on-demand or inkjet print type dispensers can be used. Stencils can be used. The die attach epoxy 380 can be an electrical conductor or an electrical insulator, depending on the application. In an example arrangement, die attach epoxy commercially available from Henkel A.G. & Co., in Dusseldorf Germany, among others, can be used. Brand names that can be used with the arrangements include LOCTITE® AbelStik die attach epoxies commercially available from Henkel, among other similar commercially available die attach epoxies.

FIG. 4B illustrates, in a further cross-sectional view, the package substrate and die attach epoxy material shown in FIG. 4A, after additional processing. In FIG. 4B, the elements are shown with a semiconductor die 305 mounted to the die pad 342 using the die attach epoxy 380. The cavity 341 in the semiconductor die 305 surrounds and contains the die attach epoxy 380. The edges 351 of the backside of semiconductor die 305 are in direct contact with the die pad 342 and are free from die attach epoxy 380. The use of the arrangements advantageously prevents the die attach epoxy 380 from bleeding out onto the surface of the die pad 342, keeping the surface of the die pad 342 outside of the area of the semiconductor die 305 available for wire bond connections, preventing defects that can occur when prior approach die mounting processes, and prior approach dies formed without the use of the arrangements, are mounted. Use of the cavity in the backside of the semiconductor dies of the arrangements advantageously prevents these defects.

FIG. 4C illustrates, in a further cross-sectional view, the elements of FIG. 4B after a wire bonding process. Bond wires 358 are shown forming wire bond connections between the device side surface of the semiconductor die 305 and the package substrate 311. Bond wires 358 form connections to the leads 344. In the example arrangement, an additional bond wire 359 forms a downbond connection between the semiconductor die 305 and the die pad 342. In some example arrangements, die pad 342 may be used as a ground plane or may be placed at another potential. Bond wire 359 couples a bond pad on the semiconductor die 305 to the die pad and therefore, to the potential. Because the use of the cavities in the semiconductor dies in the arrangements prevents die attach epoxy 380 from bleeding out onto the device side surface of the die pad 342 in areas outside of the area of the semiconductor die 305, the downbond connection made by bond wire 359 to the die pad 342 is not affected by die attach epoxy. Unlike in prior approach packaging processes, where die attach epoxy can “bleed out” onto wire bonding areas of die pads and can cause non-stick on lead (“NSOL”) wire bond defects, use of the arrangements advantageously reduces or eliminate these problems by containing the die attach epoxy during die mount processes.

FIG. 4D is another additional cross-sectional view that illustrates the elements of FIG. 4C after an additional processing step. In FIG. 4D, mold compound 323 is shown formed over portions of the package substrate 311, over the semiconductor die 305, and over the bond wires 358 and 359, to form a protective body for a microelectronic device package. In an example molding process useful with the arrangements, transfer molding can be used. In a transfer molding process, mold compound such as an epoxy resin mold compound is provided in a solid at room temperature, either in a puck form or in a powder. The mold compound is heated in a pot in the mold tool to a liquid state. Hydraulic pressure is used to force the mold compound through runners into a mold chase that surrounds the package substrate, the semiconductor dies, and the bond wires. The mold compound 323 can be a thermoset material that transitions to a solid. Epoxy resin mold compound can be used. After the molded devices are removed from the mold tool, a sawing operation can separate the devices, which can be provided in a strip, an array or a grid form, and a saw can cut through the package substrate, which can be for example a copper leadframe, and through the mold compound, in saw streets between the unit devices in order to singulate the competed microelectronic device packages devices from one another.

FIG. 4E illustrates, in a further cross-sectional view, a microelectronic device package 300 formed after a singulation process is performed on package substrate 311 of FIG. 4D. Microelectronic device package 300 is a quad flat no-lead (QFN) type package. In FIG. 4E, the microelectronic device package 300 can be formed by sawing the package substrate 311 along saw streets between unit devices. The sawing operation cuts through the mold compound and the package substrate material, in this example a copper leadframe can be used, to form individual microelectronic device packages. Semiconductor die 305 is shown mounted to the die pad 342 by die attach epoxy 380. The edges 351 of the backside surface of the semiconductor die 305 that surround the die cavity are in direct contact with the die pad 342 and are free from die attach epoxy 380. The die attach epoxy 380 has a backside surface that is coplanar with the device side surface of the edges 351 of the backside surface of the semiconductor die 305. Bond wires 358 are shown coupling the semiconductor die to the leads 344 of the package substrate 311, and bond wire 359 forms a downbond connection to the die pad 342 (note that the downbond connection is not visible in the cross sections pf FIGS. 4C-4E). Use of the arrangements results in the die attach epoxy 380 being contained within the cavity of the semiconductor die 305, so that there is no die attach epoxy on the device side surface of the die pad 342 outside of the cavity in the semiconductor die 305. Non-stick on lead defects and interference with the wire bonding process that can occur with prior die mount approaches are eliminated by the use of the arrangements.

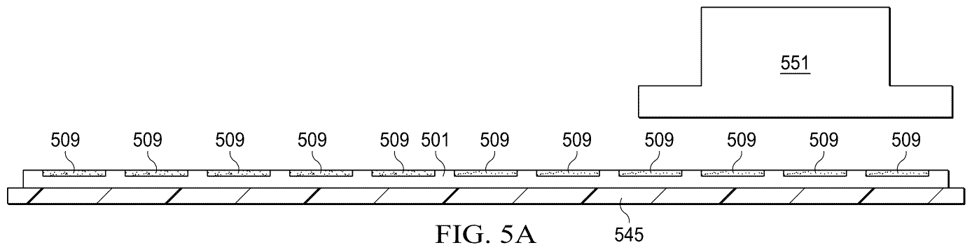

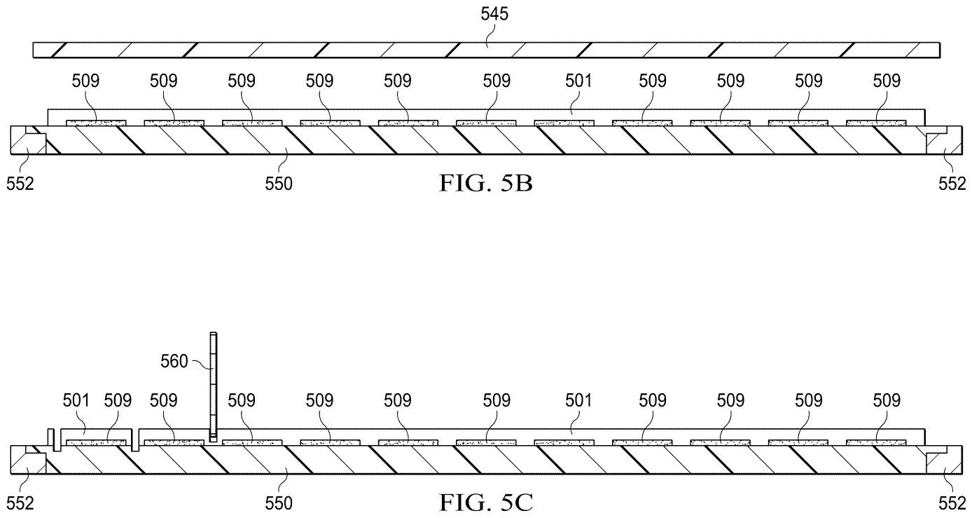

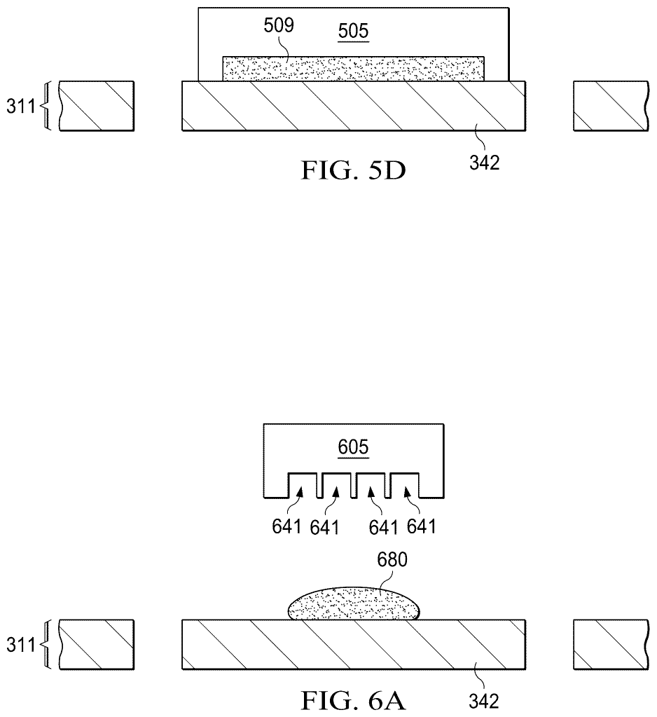

FIGS. 5A-5D illustrate, in a series of cross-sectional views, an alternative method for forming arrangements using a wafer scale die attach deposition process. In FIG. 5A, a semiconductor wafer 501 is shown mounted to a backside grinding tape 545 for support. A grinding tool 551 is shown which can be used to remove material from the semiconductor wafer 501 from the backside surface. A B-stage die attach epoxy 509 is shown deposited in cavities on the backside surface of semiconductor wafer 501. B-stage die attach epoxy has two curing steps. Because the B-stage die attach material can be partially cured in an initial deposition step, and then later cured to a final stage, the material can be deposited and stabilized in a first process step, and then the B-stage epoxy allows for additional processing at a later stage, allowing for changes in the order of steps used to assemble components. In the example shown in FIG. 5A, the use of B-stage die attach epoxy 509 allows for die attach deposition to be done on the entire wafer, prior to wafer dicing. For example, needle deposition, screen printing, stencil, or drop-on-demand processes can be used to deposit the die attach material 509. A first cure can be performed to stabilize the die attach material 509 for further processing. B-stage die attach epoxy that can be used with the arrangements is commercially available from Henkel A.G., among other vendors. In some formulations, the B-stage die attach epoxy can be cured by thermal cure, or by UV cure, in the first cure stage, and after die mounting, a final thermal cure can be used to complete the die bonding.

FIG. 5B illustrates the semiconductor wafer 501 after further processing. In FIG. 5B, the backside surface of the semiconductor wafer 501 is shown facing downwards and mounted to a dicing tape 550 in frame 552, in preparation for wafer dicing. The backgrinding tape 545 is shown being removed from the device side surface of the semiconductor wafer 501 in a de-taping process.

FIG. 5C illustrates in another cross-sectional view, the elements of FIG. 5B after additional processing. In FIG. 5C, a wafer dicing process is illustrated being used to singulate individual semiconductor dies from semiconductor wafer 501. The dicing saw 560 cuts through the semiconductor wafer 501 while traversing scribe lines (not shown in FIG. 5C, but see FIG. 1A, where scribe lines 103, 104 are shown on a semiconductor wafer 101 between the semiconductor dies 105.) The semiconductor dies have the die attach epoxy 509 in cavities on the backside surface.

FIG. 5D illustrates in a further cross-sectional view, an individual semiconductor die 505 from the semiconductor wafer 501 in FIG. 5C and mounted to package substrate 311. Package substrate 311 can be a conductive leadframe, such as a copper leadframe. The B-stage die attach epoxy 509 is used to mount the semiconductor die 505. The B-stage die attach epoxy 509 can be thermally cured to adhere the semiconductor die 505 to the die pad 342, completing the process of mounting the semiconductor die 505 to the package subtrate 311. After the process of die mounting, the semiconductor die 505 and the package substrate 311 are ready for wire bonding, molding, and package singulation in processes such as are shown in FIGS. 4C, 4D, and 4E as described above to complete a microelectronic device package.

Use of the B-stage die attach epoxy 509 in this alternative arrangement allows the die attach epoxy to be dispensed at a wafer stage, in contrast to depositing die attach epoxy on individual units of the package substrate (as described above with respect to FIGS. 4A-4B.) Either of these approaches can be used to form microelectronic device packages using the arrangements, with the semiconductor dies having cavities on backside surface to contain the die attach material, thereby accruing the advantages of the arrangements.

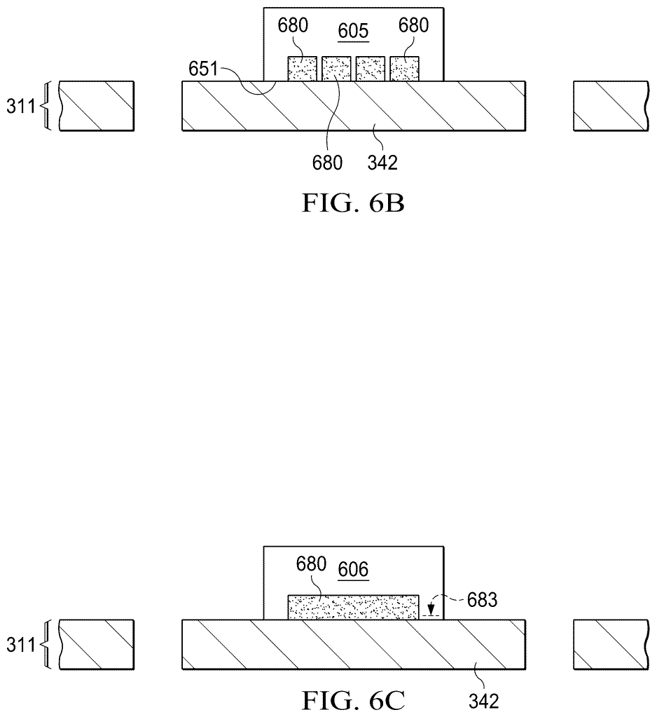

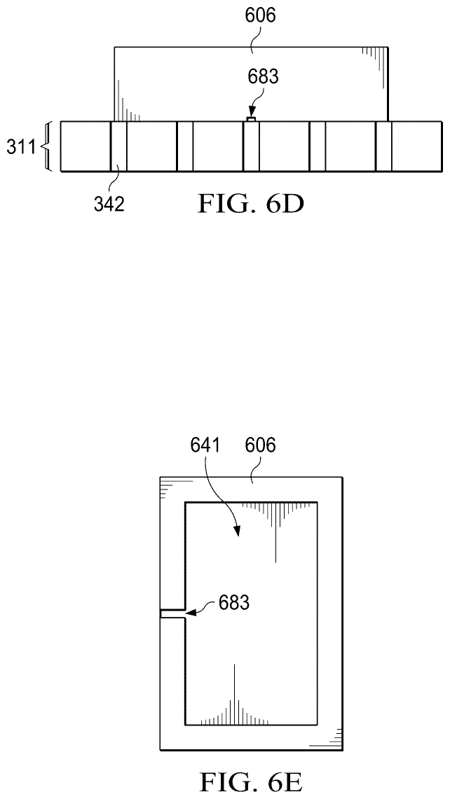

FIGS. 6A-6B illustrate, in cross-sectional views, details of an alternative arrangement using multiple cavities extending into a backside surface of a semiconductor die. FIGS. 6C-6E illustrate, in additional cross-sectional view, a further alternative arrangement having a vent hole extending from the backside cavity.

In FIG. 6A, a die mounting operation is shown as part of a process for forming an alternative arrangement. Depending on the die size, the cavity size, and the characteristics of the die attach material used, in some examples air may become trapped in the backside cavity during the die mounting, causing voids. The example arrangement illustrated in FIGS. 6A-6B reduces the likelihood that air will form pockets in the die attach material within the backside cavity, reducing or eliminating the possibility of voids. In FIG. 6A, a semiconductor die 605 is shown with multiple small cavities 641 formed and extending into the backside surface. These cavities 641 can be formed using a plasma etch process applied to the backside of a semiconductor wafer, by using the plasma etch cavity formation process shown in FIGS. 3A-3D, for example. The cavity sides can have scalloped shapes (not shown for clarity of illustration) formed by the plasma etch processes. By patterning multiple cavities extending into the backside surface of the semiconductor dies, the volume of each cavity is reduced, which eliminates or reduces the possibility that air will form pockets during die mount operations. The surface area of the semiconductor die material that contacts the die attach epoxy is increased, increasing adhesion, while the volume of the individual now smaller cavities is decreased. In FIG. 6A, the semiconductor die 605 is shown facing the device mounting surface of a die pad 342 of the package substrate 311, which can be a copper leadframe, for example. A die attach epoxy 680 is shown deposited on die pad 342 in preparation for die mounting.

FIG. 6B illustrates, in a further cross-sectional view, the elements of FIG. 6A following the die mount process. The semiconductor die 605 is shown mounted to the device mounting surface of the die pad 342 of package substrate 311, with the die attach epoxy 680 filling the multiple cavities on the backside of the semiconductor die 605. The edges 651 of the backside surface of the semiconductor die 605 make contact with the device side surface of the die pad 342 of package substrate 311, without die attach epoxy 380 being present on the die pad 342 outside of the area covered by the semiconductor die 605, the use of the arrangements reduces or eliminates any epoxy outside the area of the cavities in the semiconductor die. Epoxy bleed out that can occur in prior approach die mounting processes is reduced or eliminated by use of the arrangements.

FIGS. 6C-6E illustrate, in three views, a further alternative arrangement. In FIG. 6C, in a cross-sectional view, a semiconductor die 606 is shown with die attach epoxy 680 mounting the semiconductor die 606 to a die pad 342 of the package substrate 311. The semiconductor die 606 includes a vent hole 683. The vent hole 683 can be formed as an open trench on the backside of the semiconductor die during a plasma etch process that forms the cavities (see, for example, cavities 341 in FIG. 3B). The vent hole 683 can be formed by a trench in the backside surface of the semiconductor die 606 that is then covered by the device side of the die pad 342 when the semiconductor die 606 is mounted.

FIGS. 6D-6E illustrate, in a side view and a bottom view, additional details of the arrangement of FIG. 6C. The semiconductor die 606 is shown in a side view in FIG. 6D, with the view showing an end of the vent hole 683. The bottom view of the semiconductor die 606 is shown in FIG. 6E (the package substrate 311 is omitted in FIG. 6E for clarity of illustration), with the vent hole 683 shown as a trench extending from the periphery of the semiconductor die 606 to the cavity 641.

By providing a vent hole extending to the cavity 641 in the arrangement of FIGS. 6C-6E, during a die mount process, the die attach epoxy (see 680 in FIG. 6C) can fill the cavity (see cavity 641 in FIG. 6E) and any air can be pushed out of the cavity through the vent hole 683 during the die mount process. After the die attach epoxy is cured and the die mounting process is complete, the vent hole 683 is closed at the cavity end by the cured die attach epoxy and may be filled with the die attach epoxy.

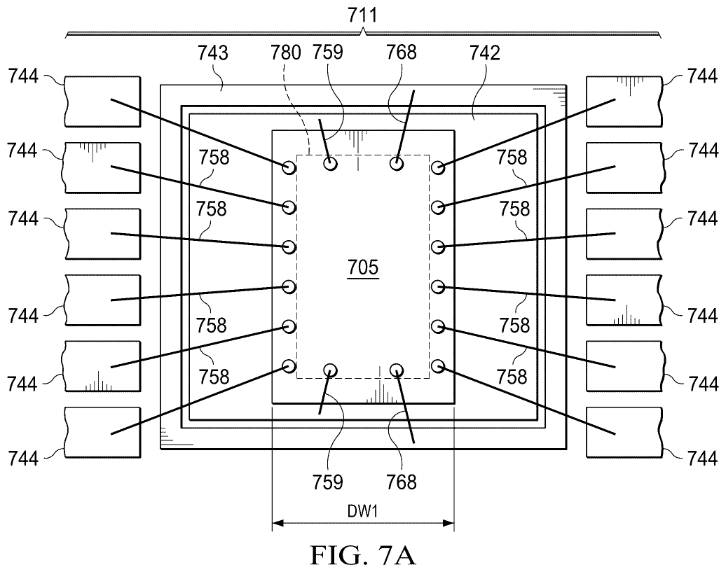

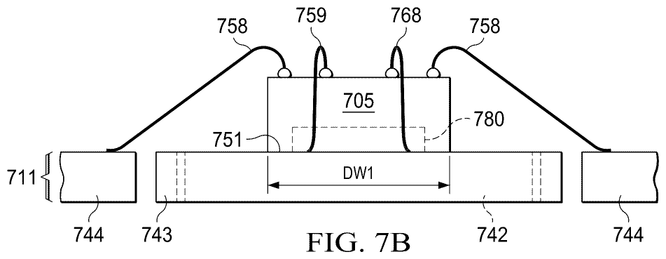

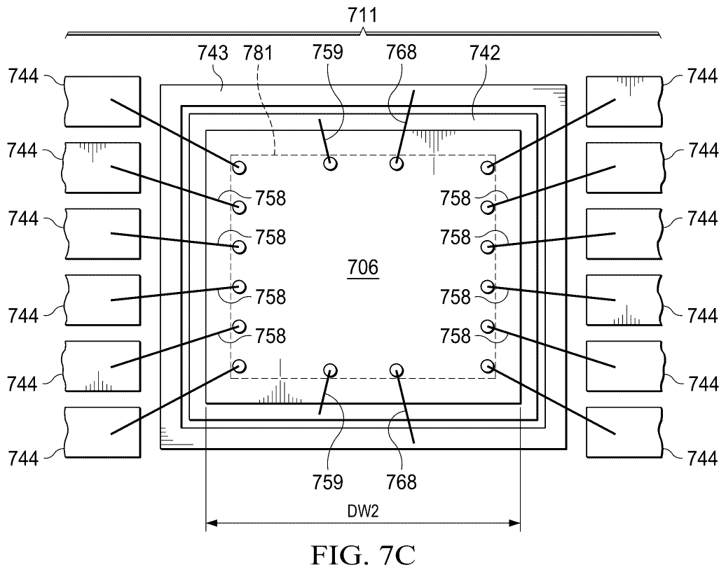

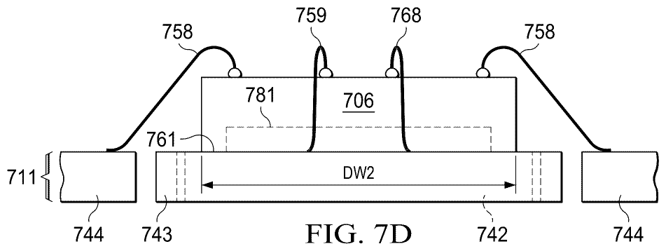

FIGS. 7A-7D illustrate, in plan views and side views, additional details of example arrangements. In FIG. 7A, a package substrate 711, which can be a copper leadframe, is shown in a plan view from a device side with leads 744 spaced from a die pad 742. A power rail 743 surrounds and is spaced from die pad 742. A semiconductor die 705 is shown mounted to the device side surface of the die pad 742. The die attach epoxy 780 is shown in a dashed line, as it is within the backside cavity of the semiconductor die and contained within the area of semiconductor die 705. Bond wires 758 couple bond pads (not shown for simplicity of illustration) of the semiconductor die 705 and leads 744 of the package substrate. Additional downbond bond wire connections couple the semiconductor die 705 to the die pad 742, and to the power rail 743. Bond wires 759 connect the semiconductor die 705 to the die pad 742. Bond wires 768 connect the semiconductor die 705 to the power rail 743. In an example application, the die pad 742 may be coupled to a potential such as a ground potential. The power ring 743 may be coupled to another potential, such as a power supply potential. The semiconductor die 705 can be a power device, for example, that couples high current signals to an output. Multiple bond wire connections such as 759, 768 can be made to provide low resistance connections from power and/or grounds to the semiconductor die 705.

FIG. 7B illustrates the elements of FIG. 7A in a side view. The package substrate 711 is shown with leads 744. The die pad 742 is shown with semiconductor die 705 mounted by die attach epoxy 780 to the device side surface of the die pad 742. Wire bond connections 758 connect the semiconductor die 705 to the leads 744. Wire bond connection 759 is shown coupling the semiconductor die 705 to the die pad 742, forming a downbond connection. Wire bond connection 768 is shown coupling the semiconductor die 705 to the power rail. By use of the arrangements, the die attach epoxy 780 is contained within the backside cavity in the semiconductor die 705, and the die attach epoxy does not bleed out into the wire bonding area of the die pad 742. Use of the arrangements reduces the total area needed for the die pad 742 to ensure that the downbond wire bond connections are not adversely affected by die attach epoxy, in sharp contrast to prior approaches for mounting semiconductor dies.

FIG. 7C illustrates, in a plan view, an additional arrangement. In FIG. 7C, the package substrate 711 is the same as the package substrate in FIG. 7A. An advantage of using semiconductor dies with backside cavities in the arrangements is that the same package substrate design can be used with semiconductor dies of various sizes. Because the requirements of conventional die attach processes, including the need for a margin between the wire bonding area (the “keep out zone”) reserved for the downbonds to the die pad, and the area where conventional die attach epoxy may spread during die mounting, are not present with the use of the arrangements, the same leadframe can be used to mount dies of various sizes, and with different pinouts, without modification. Use of a common leadframe for multiple applications reduces cost, reduces leadframe inventory and design time, and simplifies processing.

In FIG. 7C, the package substrate 711, the leads 744, the die pad 742, the power rail 743, are all the same for mounting semiconductor die 706 (shown in FIG. 7C) and the smaller semiconductor die 705 (shown in FIGS. 7A-7B). The semiconductor dies both include the backside cavities of the arrangements that contain the die attach epoxy during die mounting processes, eliminating epoxy bleed out problems found in prior approaches for mounting dies using die attach epoxy.

FIG. 7D illustrates the arrangement shown in FIG. 7C in a side view. The package substrate 711 is shown with leads 744, the die pad 742, and the power ring 743. The semiconductor die 706 is shown mounted to the device side of the package substrate 711 with die attach epoxy 781. The die attach epoxy 781 is contained within the cavity in the backside of the semiconductor die 706 during die mounting, and use of the arrangements prevent epoxy bleed out, allowing for reliable downbonds to the die pad 742.

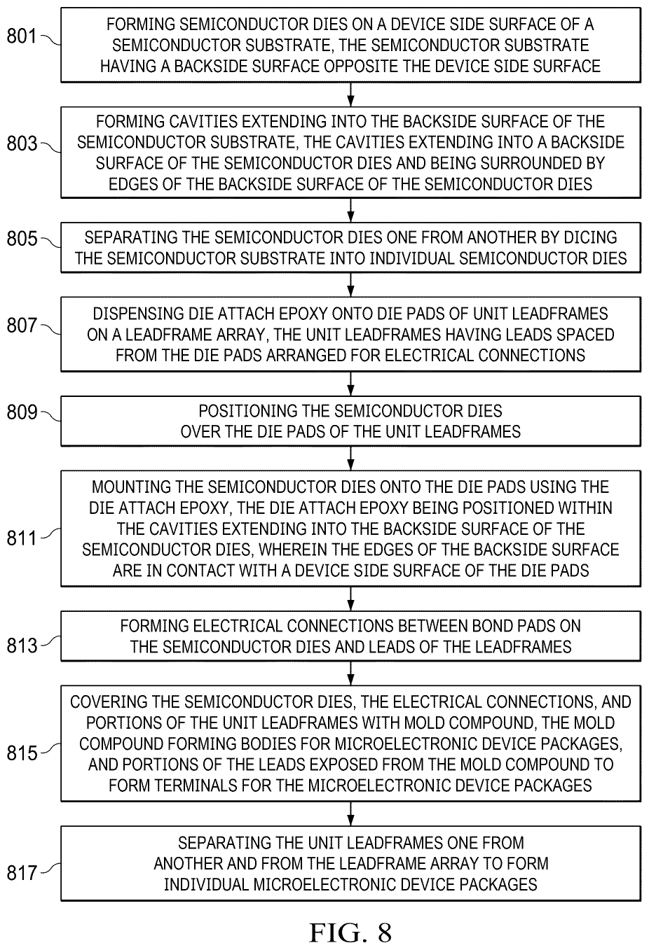

FIG. 8 illustrates, in a flow diagram, a method for forming a microelectronic device package of an arrangement. The method begins at step 801, by forming semiconductor dies on a device side surface of a semiconductor substrate, the semiconductor substrate having a backside surface opposite the device side surface. (See, for example, FIGS. 1A-1B, semiconductor substrate, wafer 101, has semiconductor dies 105 formed in a device side surface in rows and columns.)

The method continues at step 803, forming cavities extending into the backside surface of the semiconductor substrate, the cavities extending into a backside surface of the semiconductor dies and being surrounded by edges of the backside surface of the semiconductor dies. (See, for example, FIGS. 3A-3B, where cavities 341 are formed in the backside of a semiconductor substrate 301.)

The method then continues at step 805, where the semiconductor dies are separated one from another by dicing the semiconductor substrate into individual semiconductor dies. (See, for example, FIGS. 3E-3G, where a semiconductor die 305 is singulated from the semiconductor substrate 301).

At step 807, the method continues by dispensing die attach epoxy onto die pads of unit leadframes on a leadframe array, the unit leadframes having leads spaced from the die pads arranged for electrical connections. (See, for example, FIG. 4A, where the die attach epoxy 380 is dispensed on package substrate 311, on the device side of die pad 342).

At step 809, the method continues by positioning the semiconductor dies over the die pads of the unit leadframes. At step 811, the method continues by mounting the semiconductor dies onto the die pads using the die attach epoxy, the die attach epoxy being positioned within the cavities extending into the backside surface of the semiconductor dies, wherein the edges of the backside surface are in contact with a device side surface of the die pads. (See, for example, FIG. 4B, where the semiconductor die 305 is mounted to the package substrate 311, the die pad 342 is shown with die attach epoxy 380 within the cavity in the backside of the semiconductor die 305. The edges 351 of the semiconductor die 305 are shown contacting the die pad 342.

At step 813, the method continues by forming electrical connections between bond pads on the semiconductor dies and leads of the leadframes. (See, for example FIG. 4C, bond wires 358, 359 between the semiconductor die 305 and leads 344.)

At step 815, the method continues by covering the semiconductor dies, the electrical connections, and portions of the unit leadframes with mold compound, the mold compound forming bodies for microelectronic device packages, and portions of the leads exposed from the mold compound to form terminals for the microelectronic device packages. (See, for example, FIG. 4D where mold compound 323 covers the semiconductor die, the electrical connections, and portions of the package substrate 311, with terminals 344 exposed on a board side surface of the mold compound 323).

At step 817 the method completes by separating the unit leadframes one from another and from the leadframe array to form individual microelectronic device packages. (See, for example, FIG. 4E, where a microelectronic device package 500 is shown after the leadframe and mold compound are cut apart to singulate the packages from one another).

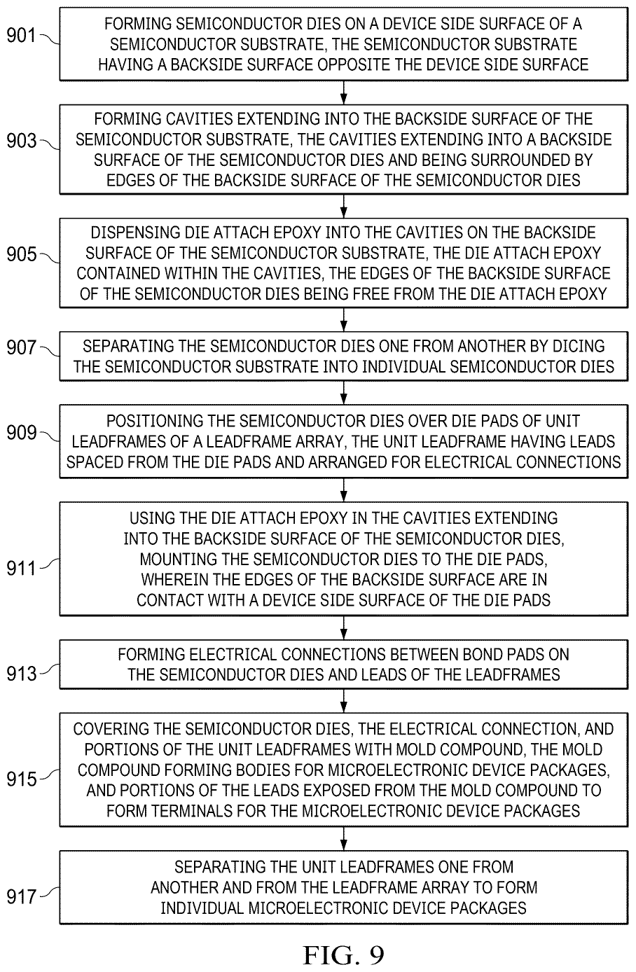

FIG. 9 illustrates, in another flow diagram, an alternative method for forming an arrangement. In FIG. 9, the method uses the die attach deposition at wafer scale, as described above, instead of dispensing the die attach on package substrates after the semiconductor dies are singulated from a semiconductor substrate.

In FIG. 9, the method begins at step 901, by forming semiconductor dies on a device side surface of a semiconductor substrate, the semiconductor substrate having a backside surface opposite the device side surface. (See, for example, FIGS. 1A-1B, where semiconductor dies 105 are singulated from a semiconductor substrate 101).

At step 903, the method forms cavities extending into the backside surface of the semiconductor substrate, the cavities extending into a backside surface of the semiconductor dies and being surrounded by edges of the backside surface of the semiconductor dies. (See, for example, FIGS. 3B-3C, where cavities 341 are formed in semiconductor substrate 301).

At step 905, the method continues by dispensing die attach epoxy into the cavities on the backside surface of the semiconductor substrate, the die attach epoxy contained within the cavities, the edges of the backside surface of the semiconductor dies being free from the die attach epoxy. (See, for example, FIG. 5A, where the die attach epoxy 509 is shown deposited in cavities on the backside of semiconductor substrate 501.)

At step 907, the method continues by separating the semiconductor dies one from another by dicing the semiconductor substrate into individual semiconductor dies. (See, for example, FIG. 5C, where a blade 560 is shown being used to separate the semiconductor dies from semiconductor substrate 501).

At step 909, the method continues by positioning the semiconductor dies over die pads of unit leadframes of a leadframe array, the unit leadframe having leads spaced from the die pads and arranged for electrical connections. At step 911, the method continues by using the die attach epoxy in the cavities extending into the backside surface of the semiconductor dies, mounting the semiconductor dies to the die pads, wherein the edges of the backside surface are in contact with a device side surface of the die pads. (See, for example, FIG. 5D, where semiconductor die 505 is shown mounted to the die pad 342 on package substrate 311.)

At step 913, the method continues by forming electrical connections between bond pads on the semiconductor dies and leads of the unit leadframes. (See, for example, FIG. 4C, where bond wires 358, 359 are shown).

At step 915, the method continues by covering the semiconductor dies, the electrical connections, and portions of the unit leadframes with mold compound, the mold compound forming bodies for microelectronic device packages, and portions of the leads of the unit leadframes exposed from the mold compound to form terminals for the microelectronic device packages. (See FIG. 4D, where mold compound 323 is shown).

At step 917, the method shown in FIG. 9 completes by separating the unit leadframes one from another and from the leadframe array to form individual microelectronic device packages.

Use of the backside cavities in the semiconductor dies of the arrangements advantageously prevents die attach epoxy from “bleeding out” and interfering with downbond connections on die pads by containing the die attach epoxy. By using the arrangements, the area needed outside the semiconductor die to enable wire bond connections to the die pad surfaces is reduce, because the die attach epoxy is entirely contained, and does not bleed into areas where wire bonding may take place, so the need for a buffer zone between the die mounting area and the wire bonding area is reduced or eliminated. Because the die attach epoxy is contained within the area of the semiconductor die, the package substrate designs can be used with large semiconductor dies and small semiconductor dies without modification of the die pad design, reducing the need for custom package substrate designs for each semiconductor die. Use of the backside cavities of the arrangements to contain the die attach epoxy enables use of the arrangements without modification to the dicing, singulation, and wire bonding tools already in use, lowering costs for adopting the arrangements in packaging processes.

Modifications and variations are contemplated and can be made in the described arrangements, and other alternative arrangements are possible that are within the scope of the claims.

What is claimed is:

1. An apparatus, comprising:
at least one semiconductor die mounted on a die pad of a package substrate, the at least one semiconductor die having a device side surface and an opposite backside surface, the at least one semiconductor die having a cavity extending into the backside surface and having edges on the backside surface around the cavity;
die attach material adhering the at least one semiconductor die to the die pad, the die attach material positioned within the cavity extending into the backside surface, the die attach material in contact with an interior surface of the cavity and in contact with the die pad, the edges of the at least one semiconductor die around the cavity directly contacting a device side surface of the die pad, wherein a backside surface of the die attach material and a plane taken along the edges of the at least one semiconductor die are coplanar;
electrical connections between bond pads on the device side surface of the at least one semiconductor die and leads formed in a device side layer of the package substrate, the leads having portions forming terminals and having a board side surface; and
mold compound covering the at least one semiconductor die, the electrical connections, and a portion of the package substrate, while the board side surface of the terminals is exposed from the mold compound, the mold compound forming a body of a microelectronic device package for the at least one semiconductor die.

2. The apparatus of claim 1 wherein the microelectronic device package comprises a quad flat no-lead (QFN) microelectronic device package with terminals on each of the four sides.

3. The apparatus of claim 1, wherein the electrical connections are wire bond connections.

4. The apparatus of claim 3, and further comprising the at least one semiconductor die covering a portion of the die pad of the package substrate, and the die pad having a portion of the device side surface that is outside the portion covered by the at least one semiconductor die, and at least one downbond electrical connection between a bond pad on the at least one semiconductor die and the device side surface of the die pad.

5. The apparatus of claim 1, wherein the package substrate is a copper leadframe.

6. The apparatus of claim 1, wherein the die attach material is a conductive die attach epoxy.

7. The apparatus of claim 1, wherein the die attach material is a non-conductive die attach epoxy.

8. The apparatus of claim 1, wherein the electrical connections are copper bond wires.

9. The apparatus of claim 1, wherein the microelectronic device package is a quad flat no-lead package.

10. The apparatus of claim 1, wherein the electrical connections are wire bond connections, and further comprising the at least one semiconductor die covering a portion of the die pad of the package substrate, and the die pad having a portion of the device side surface that is outside the portion covered by the at least one semiconductor die, and at least one downbond electrical connection between a bond pad on the at least one semiconductor die and the device side surface of the die pad.

11. The apparatus of claim 10, and further comprising the package substrate having a power rail surrounding and spaced from the die pad, and an additional wire bond connection that is a downbond connection between a bond pad on the at least one semiconductor die and the power rail.

12. The apparatus of claim 1, wherein the cavity further comprises a plurality of die cavities, each containing a portion of the die attach material.

13. The apparatus of claim 1, wherein the cavity has sidewalls extending into the semiconductor die from the backside surface and the sidewalls have scallop shaped sides.

14. The apparatus of claim 1, wherein the at least one semiconductor die has sides extending between the device side surface and the backside surface, the sides having scalloped shapes.

15. The apparatus of claim 1, wherein the at least one semiconductor die has sides extending between the device side surface and the backside surface, the sides having stress lines formed in laser dicing.

16. The apparatus of claim 1, wherein the at least one semiconductor die has sides extending between the device side surface and the backside surface, the sides having abraded surfaces formed by mechanical dicing by a rotating blade.

17. A method, comprising:
forming semiconductor dies on a device side surface of a semiconductor substrate, the semiconductor substrate having a backside surface opposite the device side surface;
forming cavities extending into the backside surface of the semiconductor substrate, the cavities extending into a backside surface of the semiconductor dies and being surrounded by edges of the backside surface of the semiconductor dies;
separating the semiconductor dies one from another by dicing the semiconductor substrate into individual semiconductor dies;
dispensing die attach epoxy onto die pads of unit leadframes on a leadframe array, the unit leadframes having leads spaced from the die pads, the leads arranged for electrical connections;
positioning the semiconductor dies over the die pads of the unit leadframes;
mounting the semiconductor dies onto the die pads using the die attach epoxy, the die attach epoxy being positioned within and contacting the surfaces of the cavities of the semiconductor dies and a device side surface of the die pads, wherein the edges of the backside surface of the semiconductor dies are in direct contact with the device side surface of the die pads;
forming electrical connections between bond pads on the semiconductor dies and leads of the unit leadframes;
covering the semiconductor dies, the electrical connections, and portions of the unit leadframes with mold compound, the mold compound forming bodies for microelectronic device packages, and portions of the leads exposed from the mold compound to form terminals for the microelectronic device packages; and
separating the unit leadframes one from another and from the leadframe array to form individual microelectronic device packages.

18. The method of claim 17, wherein forming the cavities extending into the backside surface of the semiconductor substrate, the cavities extending into a backside surface of the semiconductor dies and being surrounded by edges of the backside surface of the semiconductor dies further comprises performing a plasma etch on the backside surface of the semiconductor substrate.

19. The method of claim 18, wherein the plasma etch comprises a Bosch process.

20. The method of claim 17, wherein forming electrical connections further comprises forming wire bonds between the bond pads of the semiconductor dies and the leads of the unit leadframes.

21. The method of claim 20, and further comprising the unit leadframes having a portion of the die pad covered by the semiconductor dies, and having another portion of the die pads outside the portion covered by the semiconductor dies, and forming a downbond wire bond connection between a bond pad on the semiconductor dies and the another portion of the die pads.

22. The method of claim 21, and further comprising forming an additional downbond wire bond connection between another bond pad on the semiconductor dies and power rails of the unit leadframes, the power rails spaced from and surrounding the die pads.

23. The method of claim 17, wherein the die attach epoxy is an electrically conductive die attach epoxy.

24. The method of claim 17, wherein the die attach epoxy is an electrically non-conductive die attach epoxy.

25. The method of claim 17, wherein after mounting the semiconductor dies, the edges of the backside surface of the semiconductor dies are free from the die attach epoxy, and the edges of the backside surface directly contact the device side surface of the die pads.

26. A method, comprising:
forming semiconductor dies on a device side surface of a semiconductor substrate, the semiconductor substrate having a backside surface opposite the device side surface;
forming cavities extending into the backside surface of the semiconductor substrate, the cavities extending into a backside surface of the semiconductor dies and being surrounded by edges of the backside surface of the semiconductor dies;
dispensing die attach epoxy into the cavities on the backside surface of the semiconductor substrate, the die attach epoxy contained within the cavities, the edges of the backside surface of the semiconductor dies being free from the die attach epoxy;
separating the semiconductor dies one from another by dicing the semiconductor substrate into individual semiconductor dies;
positioning the semiconductor dies over die pads of unit leadframes of a leadframe array, the unit leadframe having leads spaced from the die pads and arranged for electrical connections;
using the die attach epoxy in the cavities extending into the backside surface of the semiconductor dies, mounting the semiconductor dies to the die pads, wherein the edges of the backside surface are in contact with a device side surface of the die pads;
forming electrical connections between bond pads on the semiconductor dies and leads of the unit leadframes;
covering the semiconductor dies, the electrical connections, and portions of the unit leadframes with mold compound, the mold compound forming bodies for microelectronic device packages, and portions of the leads of the unit leadframes exposed from the mold compound to form terminals for the microelectronic device packages; and
separating the unit leadframes one from another and from the leadframe array to form individual microelectronic device packages.

27. The method of claim 26, wherein dispensing die attach epoxy into the cavities on the backside surface of the semiconductor substrate further comprises dispensing B-stage die attach epoxy and performing a first cure to set the B-stage die attach epoxy.

28. The method of claim 27, wherein using the die attach epoxy in the cavities extending into the backside surface of the semiconductor dies, wherein the edges of the backside surface are in contact with a device side surface of the die pads further comprises performing a second cure of the B-stage die attach epoxy to mount the semiconductor dies to the die pads.

29. The method of claim 27, wherein forming cavities extending into the backside surface of the semiconductor substrate, the cavities extending into a backside surface of the semiconductor dies and being surrounded by edges of the backside surface of the semiconductor dies further comprises performing a plasma etch on the backside surface of the semiconductor substrate, the cavities having sidewalls extending into the backside surface of the semiconductor substrate with scalloped shapes on the sides.

30. The method of claim 29, wherein performing a plasma etch further comprises performing a Bosch process.
